(19) United States
(12) Patent Application Publication
(10) Pub. No.: US 2013/0182498 A1
(43) Pub. Date: Jul. 18, 2013

(54) MAGNETIC MEMORY DEVICE AND DATA WRITING METHOD FOR MAGNETIC MEMORY DEVICE

(71) Applicant: Fujitsu Limited, Kawasaki-shi (JP)

(72) Inventor: Masaki AOKI, Kawasaki (JP)

(73) Assignee: FUJITSU LIMITED, Kawasaki-shi (JP)

(21) Appl. No.: 13/721,342

(22) Filed: Dec. 20, 2012

(30) Foreign Application Priority Data
Jan. 18, 2012 (JP) 2012-008165

(51) Int. Cl. G11C 11/16

(52) U.S. Cl. CPC G11C 11/1675
USPC 365/158

(57) ABSTRACT

A magnetic memory device including a plurality of memory cells, each of which stores therein 2ⁿ-valued data by series-connecting MTJ elements whose writing current values and resistance values are different and whose number is n, the magnetic memory device including: a first current driver configured to perform writing on a first MTJ element of a first writing current value in the n MTJ elements; a second current driver configured to perform writing on a second MTJ element of a second writing current value lower than the first writing current value in the n MTJ elements; and a control circuit configured to control so that, in the plural memory cells corresponding to a plurality of addresses, after data writing has been performed on the first MTJ element owing to the first current driver, data writing is performed on the second MTJ element owing to the second current driver.

### CROSS-REFERENCE TO RELATED APPLICATION(S)

This application is based upon and claims the benefit of priority of the prior Japanese Patent Application No. 2012-008165, filed on Jan. 18, 2012, the entire contents of which are incorporated herein by reference.

1. Field

The embodiments discussed herein are related to a magnetic memory device and a data writing method for a magnetic memory device.

2. Background

In recent years, as one of memories replacing flash memories, a magnetic memory device such as a Magnetoresistive Random Access Memory (MRAM) has drawn attention. While having the function of a non-volatile memory, such a magnetic memory device has, for example, a high-speed access performance equivalent to a Static Random Access Memory (SRAM).

In addition, in the magnetic memory device, since a memory cell stores therein information owing to not electric charge in such a way as a semiconductor memory of the related art but a magnetic moment, the memory cell is immune to a leak or galling, and furthermore, it may be possible to realize storage of data and unlimited rewrite cycles even under a high-temperature environment.

Therefore, for example, in place of SRAMs or battery-driven Dynamic Random Access Memories (DRAMs), magnetic memories device such as MRAMs have been used. Furthermore, the magnetic memory devices are increasingly expected to be used as non-volatile memories for portable devices such as a mobile phone and a digital camera.

Incidentally, in the past, a magnetic memory device (MRAM) has been proposed that stores therein four-valued (two-bit) data with series-connecting two Magnetic Tunnel Junction (MTJ) elements whose sizes are different.

[NON PATENT DOCUMENT] T. Ishigaki et al., “A Multi-Level-Cell Spin-Transfer Torque Memory with Series-Stacked Magnetotunnel Junctions,” 2010 Symposium on VLSI Technology Digest of Technical Papers pp. 47-48, June 2010.

As described above, in the past, the multiple-valued (four-valued) MRAM has been proposed that stores (saves) therein four-valued data with series-connecting (laminating) two MTJ elements whose sizes are different.

After, for example, having performed writing on an MTJ element whose writing current is high and which is used for a lower bit (Least Significant Bit: LSB), this MRAM performs writing on an MTJ element whose writing current is low and which is used for an upper bit (Most Significant Bit: MSB).

### SUMMARY

According to an aspect of the invention, a magnetic memory device including a plurality of memory cells, each of which stores therein 2ⁿ-valued data by series-connecting MTJ elements whose writing current values and resistance values are different and whose number is n (n is a natural number greater than or equal to 2), the magnetic memory device including: a first current driver configured to perform writing on a first MTJ element of a first writing current value in the n MTJ elements; a second current driver configured to perform writing on a second MTJ element of a second writing current value lower than the first writing current value in the n MTJ elements; and a control circuit configured to control so that, in the plural memory cells corresponding to a plurality of addresses, after data writing has been performed on the first MTJ element owing to the first current driver, data writing is performed on the second MTJ element owing to the second current driver.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram schematically illustrating an example of a magnetic memory device storing therein four-valued data;

FIG. 2 is a diagram illustrating an equivalent circuit of the magnetic memory device in FIG. 1;

FIG. 3 is a diagram for explaining an operation of each MTJ element in the magnetic memory device in FIG. 1;

FIG. 4 is a diagram for explaining an operation of the magnetic memory device in FIG. 1;

FIG. 5 is a diagram for explaining an example of a data writing method for a magnetic memory device;

FIG. 6 is a diagram for explaining a data writing method for a magnetic memory device of a first embodiment;

FIG. 7 is a diagram illustrating an example of data written into a magnetic memory device;

FIG. 8 is a diagram illustrating writing processing due to the data writing method of the first embodiment with comparing the writing processing with writing processing due to the writing method in FIG. 5;

FIG. 9 is a diagram for explaining charge and discharge in an inverter as an example of a CMOS circuit;

FIG. 10 is a diagram comparing and illustrating estimation of power consumption with applying a comparison result illustrated in FIG. 8 to the CMOS circuit in FIG. 9;

FIG. 11 is a diagram comparing and illustrating estimation of a delay time with applying the comparison result illustrated in FIG. 8 to the CMOS circuit in FIG. 9;

FIG. 12 is a diagram schematically illustrating another example of the magnetic memory device to which the data writing method of the first embodiment is applied;

FIG. 13 is a diagram for explaining a data writing method for a magnetic memory device of a second embodiment;

FIG. 14 is a diagram illustrating an equivalent circuit of a magnetic memory device to which the data writing method of the second embodiment is applied;

FIG. 15 is a diagram illustrating another example of data written into a magnetic memory device;

FIG. 16 is a diagram illustrating writing processing due to the data writing method of the second embodiment with comparing the writing processing with writing processing equivalent to the writing method in FIG. 5;

FIG. 17 is a diagram comparing and illustrating estimation of power consumption with applying a comparison result illustrated in FIG. 16 to the CMOS circuit in FIG. 9;

FIG. 18 is a diagram comparing and illustrating estimation of a delay time with applying the comparison result illustrated in FIG. 16 to the CMOS circuit in FIG. 9;

FIG. 19 is a block diagram illustrating an embodiment of a magnetic memory device;

FIG. 20 is a block diagram illustrating in more detail the magnetic memory device illustrated in FIG. 19;

FIG. 21 is a diagram for explaining an example of an operation of a control circuit in FIG. 20; and

FIG. 22 is a block diagram illustrating an example of a modification to the magnetic memory device illustrated in FIG. 20.

### DESCRIPTION OF EMBODIMENTS

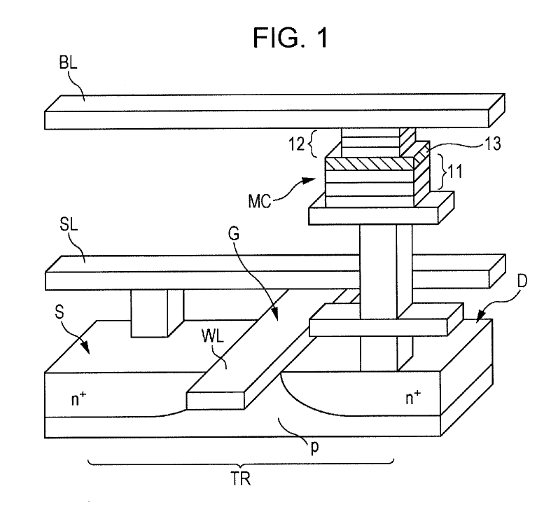

First, before describing in detail embodiments of a magnetic memory device and a data writing method for a magnetic memory device, an example of a magnetic memory device storing therein four-valued data will be described with reference to FIG. 1 to FIG. 5.

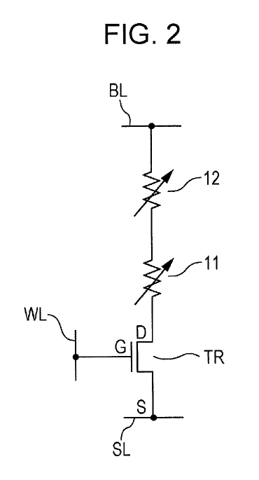

FIG. 1 is a diagram schematically illustrating an example of a magnetic memory device storing therein four-valued data, and a diagram illustrating a four-valued spin injection type MRAM (Spin Transfer Torque Magnetoresistive Random Access Memory). In addition, FIG. 2 is a diagram illustrating the equivalent circuit of the magnetic memory device in FIG. 1.

In FIG. 1 and FIG. 2, reference symbols 11, 12, and 13 illustrate a first Magnetic Tunnel Junction (MTJ) element, a second MTJ element, and an intermediate metal layer, respectively. In addition, reference symbols TR, BL, SL, WL, S, and D illustrate a transistor (n-channel type MOS transistor), a bit line, a source line, a word line (gate G), a source, and a drain, respectively.

As illustrated in FIG. 1 and FIG. 2, a four-valued spin injection type MRAM cell MC includes the two MTJ elements 11 and 12 series-connected through the intermediate metal layer 13, and the spin injection type MRAM includes a memory cell array where a plurality of MRAM cells MC are disposed in a matrix state.

In other words, each MRAM cell MC including the two MTJ elements 11 and 12 series-connected through the intermediate metal layer 13 is disposed between the drain D of the transistor TR and the bit line BL.

The transistor TR is formed owing to two n⁺ regions functioning as the source S and the drain D and the word line WL functioning as the gate G provided between the source S and the drain D thereof.

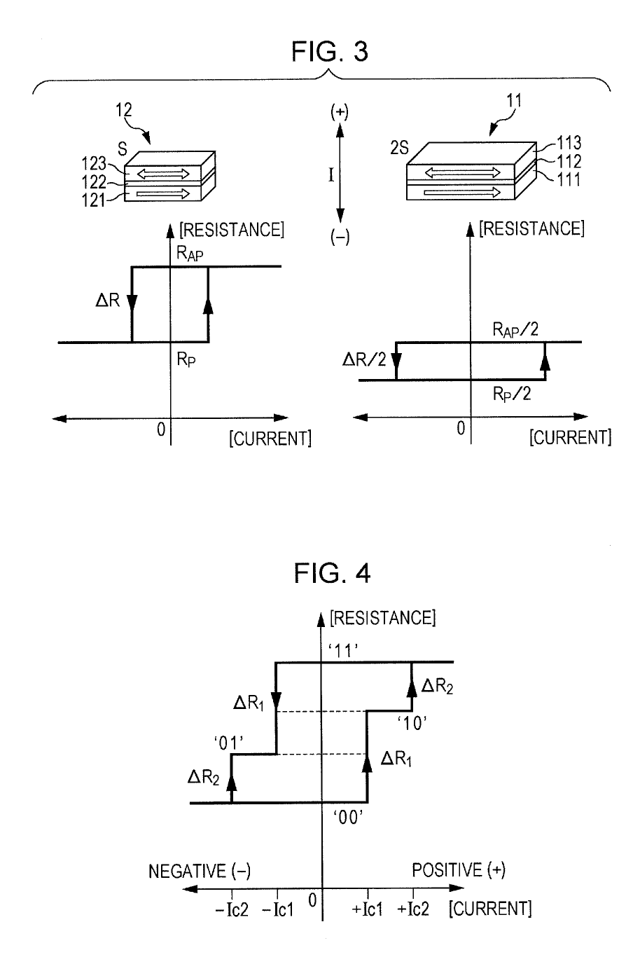

FIG. 3 is a diagram for explaining the operation of each MTJ element in the magnetic memory device in FIG. 1, and FIG. 4 is a diagram for explaining the operation of the magnetic memory device in FIG. 1.

In FIG. 3, each of reference symbols 111 and 121 illustrate a first magnetic material layer (pin layer) whose magnetization direction is fixed, each of reference symbols 112 and 122 illustrate a tunnel barrier film (insulation layer), and each of reference symbols 113 and 123 illustrate a second magnetic material layer (free layer) whose magnetization direction is to be inverted owing to a current.

Here, the MTJ element 11 and the MTJ element 12 are caused to have a same structure and different sizes (areas), namely, the area 2S of the MTJ element 11 is caused to be twice as large as the area S of the MTJ element 12.

In addition, when, in each of the MTJ elements 11 and 12, the magnetization directions (spins) of the pin layer 111 or 121 and the free layer 113 or 123 are equal to each other, a resistance value becomes small (a current flowing through an element becomes large), and it is assumed that data at that time is “0”.

On the contrary, when, in each of the MTJ elements 11 and 12, the magnetization directions (spins) of the pin layer 111 or 121 and the free layer 113 or 123 are opposite to each other, a resistance value becomes large (a current flowing through the element becomes small), and it is assumed that data at that time is “1”.

As illustrated in FIG. 3, since the MTJ element 11 has the area (2S) twice as large as the MTJ element 12, the resistance value of the MTJ element 11 at the time of data being “0” becomes one-half (Rₚ/2) of the resistance value Rₚ of the MTJ element 12 at the time of data being “0”.

In addition, the resistance value of the MTJ element 11 at the time of data being “1” becomes one-half (R_{AP}/2) of the resistance value R_{AP} of the MTJ element 12 at the time of data being “1”.

Furthermore, the change of the resistance value of the MTJ element 11 between the data “0” and the data “1” becomes one-half (ΔR/2) of the change ΔR of the resistance value of the MTJ element 12 between the data “0” and the data “1”.

Accordingly, as a whole element (memory cell) where both of the two MTJ element 11 and the MTJ element 12 are series-connected, for example, when a current is gradually increased from zero (the current is increased in a positive direction), a state (memory state) changes from “00”, to “10”, and to “11”.

Furthermore, when, in a state “11”, when a current is gradually decreased from zero (the current is increased in a negative direction), the state changes from “11”, to “01”, and to “00”.

In this way, it may be possible for the magnetic memory device (the MRAM where the two MTJ elements 11 and 12 are series-connected) illustrated in FIG. 1 to hold “00”, “10”, “11”, and “01” serving as four memory states (four-valued data).

Here, after, for example, having performed writing on the MTJ element 11 whose writing current is high and which is used for a lower bit, the MRAM (four-valued MRAM cell) where the two MTJ elements 11 and 12 are series-connected performs writing on the MTJ element 12 whose writing current is low and which is used for an upper bit.

In addition, while, in the above description, the MTJ element 11 and the MTJ element 12 are caused to have the same structure and different areas, the MTJ element 11 and the MTJ element 12 are not limited to that, and the structures themselves of the two MTJ elements may be caused to be different.

In other words, various MRAM cells may be adopted if each of the MRAM cells is a four-valued MRAM cell (the memory cell of a four-valued MRAM) in which two MTJ elements having different write and readout characteristics are laminated and which has four memory states.

In addition, in FIG. 1, the intermediate metal layer 13 is provided between the MTJ element 11 and the MTJ element 12, which may not be adopted in a limited way.

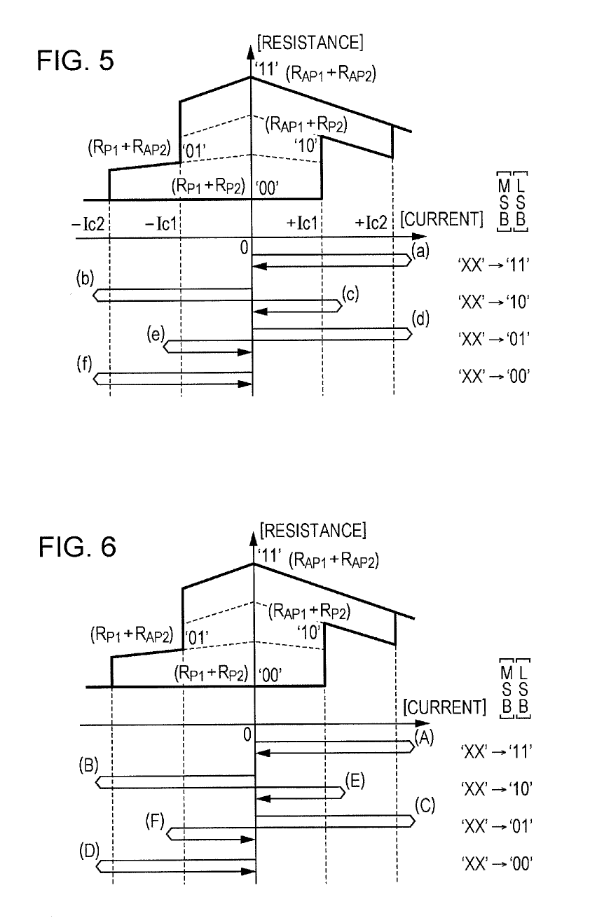

FIG. 5 is a diagram for explaining an example of a data writing method for a magnetic memory device, and a diagram illustrating the applying order of pulses when pieces of data, “11”, “10”, “01”, and “00”, are written into a memory cell where the above-mentioned two MTJ elements are laminated (series-connected). Here, “XX” indicates that the memory cell may be in an arbitrary state.

As described above, when data is written into the four-valued MRAM cell where the two MTJ elements 11 and 12 are laminated, writing of data is performed first on the MTJ element 11 of a lower bit (LSB) where the absolute value of a writing current Ic is larger (a resistance value is smaller).

After that, writing of data is performed on the MD element 12 of an upper bit (MSB) where the absolute value of the writing current Ic is smaller (a resistance value is larger).

Here, as for the direction of the current Ic, a positive (+) direction is a direction causing a magnetization direction to be antiparallel (high resistance: data is “1”), and on the contrary, the negative (−) direction of the current Ic is a direction causing the magnetization direction to be parallel (low resistance: data is “0”).

In addition, since so-called “overwriting” is performed on the MRAM, an erase operation before writing may not be performed in such a way as, for example, a flash memory. As for this, since “overwriting” is adopted for not only the four-valued MRAM but also a two-valued MRAM, the erase operation before writing may not be performed.

Specifically, when data “11” is written into the four-valued MRAM cell in a state of an arbitrary state “XX”, a current, +Ic2, is applied ((a) in FIG. 5). Accordingly, the resistance value of the four-valued MRAM cell becomes R_{AP1}+R_{AP2}.

In addition, when data “10” is written into the MRAM cell in the state of “XX”, a current, −Ic2, is applied ((b) in FIG. 5), and after that, a current, +Ic1, is applied ((c) in FIG. 5). Accordingly, the resistance value of the MRAM cell becomes R_{AP1}+R_{P2}.

Furthermore, when data “01” is written into the MRAM cell in the state of “XX”, a current, +Ic2, is applied ((d) in FIG. 5), and after that, a current, −Ic1, is applied ((e) in FIG. 5). Accordingly, the resistance value of the MRAM cell becomes R_{P1}+R_{AP2}.

In addition, when data “00” is written into the MRAM cell in the state of “XX”, a current, −Ic2, is applied ((f) in FIG. 5). Accordingly, the resistance value of the MRAM cell becomes R_{P1}+R_{P2}.

In the above-mentioned description, when a plurality of pieces of data are written, namely, pieces of data are written into a plurality of MRAM cells corresponding to a plurality of addresses, processing operations corresponding to the above-mentioned pieces of data are individually performed on individual MRAM cells.

For example, when four different pieces of data, “11”, “10”, “01”, and “00”, are written into four four-valued MRAM cells corresponding to four addresses, the above-mentioned processing operation (a), processing operations (b) and (c), processing operations (d) and (e), and processing operation (f) in FIG. 5 are performed.

Accordingly, switching between a high-current drive circuit used for writing of the currents, ±Ic2, whose absolute values are large and a low-current drive circuit used for writing of the currents, ±Ic1, whose absolute values are small is performed four times in such a way as (b)→(c), (c)→(d), (d)→(e), and (e)→(f).

Since charge and discharge of electric charge are performed at a switching point between the high-current drive circuit (high-current driver) and the low-current drive circuit (low-current driver), it leads to an increase in power consumption and the reduction of an operation speed.

Hereinafter, embodiments of a magnetic memory device and a data writing method for a magnetic memory device will be described in detail with reference to accompanying drawings. FIG. 6 is a diagram for explaining a data writing method for a magnetic memory device of a first embodiment.

Here, FIG. 6 is a diagram corresponding to the data writing method described with reference to the above-mentioned FIG. 5, and in the data writing method of the first embodiment illustrated in FIG. 6, the processing operations (a) to (f) in FIG. 5 are defined as processing operations (A) to (F).

As illustrated in FIG. 6, in the data writing method of the present first embodiment, when data is written into a four-valued MRAM cell in the state of the arbitrary state “XX”, writing processing of the currents, ±Ic2, whose absolute values are large is performed first on a plurality of addresses using a high-current drive circuit. After that, writing processing of the currents, ±Ic1, whose absolute values are small is performed on the plural addresses using a low-current drive circuit.

For example, when four different pieces of data, “11”, “10”, “01”, and “00”, are written into four four-valued MRAM cells corresponding to four addresses, the processing operations (E) and (F) are performed after the processing operations (A) to (D) have been performed, in the present first embodiment as illustrated in FIG. 6.

In other words, the writing processing operations (A) to (D) of the currents, ±Ic2, whose absolute values are large are performed first on the basis of the high-current drive circuit (high-current driver), and after that, the writing processing operations (E) and (F) of the currents, ±Ic1, whose absolute values are small are performed on the basis of the low-current drive circuit (low-current driver).

Accordingly, the number of times switching is performed between the high-current driver used for writing of the currents, ±Ic2, whose absolute values are large and the low-current driver used for writing of the currents, ±Ic1, whose absolute values are small is reduced to one in such a way as (D)→(E).

The data writing method for the magnetic memory device of the present first embodiment is a data writing method where writing is performed on the four-valued MRAM cell, in which the two MTJ elements 11 and 12 different in the writing current Ic and the resistance value are series-connected, and writing whose Ic is larger is performed first, and writing whose Ic is smaller is performed next.

In other words, writing processing operations due to +Ic2 and −Ic2 are performed first where the absolute value of the writing currents thereof are large, and after that, writing processing operations due to +Ic1 and −Ic1 are performed where the absolute value of the writing currents thereof are small.

Here, as for the data writing method for the magnetic memory device, while it is desirable that the writing processing operations whose writing currents Ic are small are performed after the writing processing operations whose writing currents Ic are large have been performed, these processing operations may not be continuously performed with respect to each address.

Therefore, in the data writing method for the magnetic memory device of the present first embodiment, usually, owing to the above-mentioned processing in FIG. 6, writing is performed for a plurality of pieces of data for a plurality of addresses such as 8 bits or 16 bits handled in a single writing processing operation.

In other words, the writing processing operations due to the ±Ic2 are performed first where the absolute values of the writing currents thereof are large, and after that, the writing processing operations due to the ±Ic1 are performed where the absolute values of the writing currents thereof are small.

According to the data writing method for the magnetic memory device of the present first embodiment, by reducing the number of times switching of a writing current drive circuit whose load capacitance is large is performed, power consumption at the time of writing is reduced, and a time taken for charge and discharge is shortened. Therefore, it may be possible to speed up a writing operation.

In addition, while the present first embodiment may be applied to, for example, the four-valued spin injection type MRAM having a plurality of MRAM cells in each of which the two MTJ elements 11 and 12 having the same structure and different areas are series-connected, the four-valued spin injection type MRAM having been described with reference to FIG. 1 and FIG. 2, the present first embodiment is not limited to this.

In other words, in the data writing method for the magnetic memory device of the present first embodiment, for example, the structures themselves of the two MTJ elements may be caused to be different. Furthermore, the data writing method for the magnetic memory device of the present first embodiment is not limited to writing processing performed on a four-valued MRAM cell, and may also be applied to, for example, writing processing performed on an eight-valued MRAM cell, as described later.

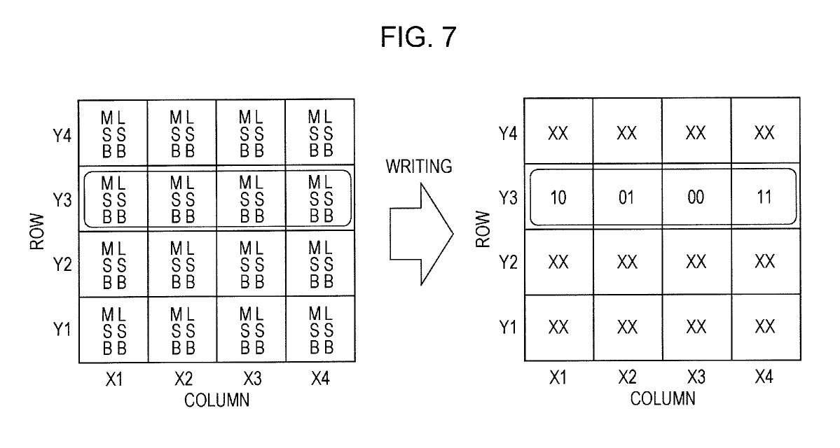

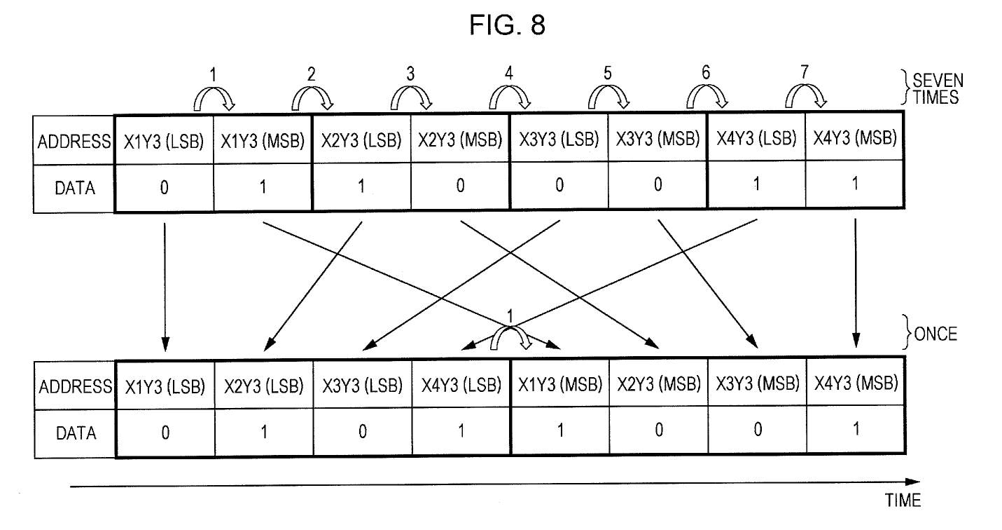

FIG. 7 is a diagram illustrating an example of data written into a magnetic memory device, and FIG. 8 is a diagram illustrating writing processing due to the data writing method of the first embodiment with comparing the writing processing with writing processing due to the writing method in FIG. 5.

FIG. 7 illustrates a case where, in a 4×4 memory cell array, one-byte data (eight bits) including “10”, “01”, “00”, and “11” is written into addresses, “X1Y3”, “X2Y3”, “X3Y3”, and “X4Y3”.

The upper half of FIG. 8 illustrates processing performed when the data writing method for the magnetic memory device, described with reference to FIG. 5, is applied and the lower half of FIG. 8 illustrates processing performed when the data writing method for the magnetic memory device of the present first embodiment, described with reference to FIG. 6, is applied.

First, as illustrated in the upper half of FIG. 8, when one-byte data is written into four addresses illustrated in FIG. 7 with the data writing method in FIG. 5 being applied, the number of times switching is performed between a high-current driver and a low-current driver becomes seven.

In other words, since, with respect to each of the four addresses, the writing processing for the LSB (the first MTJ element 11) and the writing processing for the MSB (the second MTJ element 12) are performed, switching between the writing currents, ±Ic2 and ±Ic1, is performed seven times.

On the other hand, as illustrated in the lower half of FIG. 8, when one-byte data is written into four addresses illustrated in FIG. 7 with the data writing method of the first embodiment in FIG. 6 being applied, the number of times switching is performed between the high-current driver and the low-current driver becomes one.

In other words, since the writing processing for all the MSBs (the second MTJ elements 12) is performed after the writing processing for all the LSBs (the first MTJ elements 11) has been performed, the number of times switching is performed between the writing currents, ±Ic2 and ±Ic1, becomes only one.

Specifically, as is clear from arrows in FIG. 8, when the data writing method of the present first embodiment is applied, first the writing processing of the writing currents, ±Ic2, is performed on the LSB of the address of “X1Y3”, the LSB of the address of “X2Y3”, the LSB of the address of “X3Y3”, and the LSB of the address of “X4Y3”.

After that, the writing processing of the writing currents, ±Ic1, is performed on the MSB of the address of “X1Y3”, the MSB of the address of “X2Y3”, the MSB of the address of “X3Y3”, and the MSB of the address of “X4Y3”. Accordingly, switching between the high-current driver used for the writing of the currents, ±Ic2, whose absolute values are large and the low-current driver used for the writing of the currents, ±Ic1, whose absolute values are small is performed between the LSB of “X4Y3” and the MSB of “X1Y3” only once.

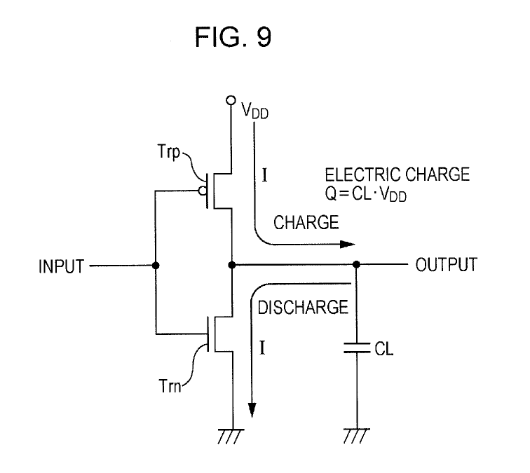

FIG. 9 is a diagram for explaining charge and discharge in an inverter as an example of a CMOS circuit. In an actual magnetic memory device, while, owing to various factors, power consumption (delay time) changes that occurs when switching between the high current driver and the low-current driver is performed, an inverter is cited as an example and will be described, for the sake of simplifying description.

As illustrated in FIG. 9, in an inverter based on a p-channel type MOS transistor Trp and an n-channel type MOS transistor Trn, when it is assumed that the load capacitance thereof is CL, electric charge Q discharged or charged becomes Q=I·t=CL·VDD. Here, the “I” indicates a current flowing at the time of discharge or charge, and the “t” indicates a delay time.

Accordingly, power consumption P per one cycle may be expressed as P=CL·VDD², and the delay time t may be expressed as t=CL·VDD/I.

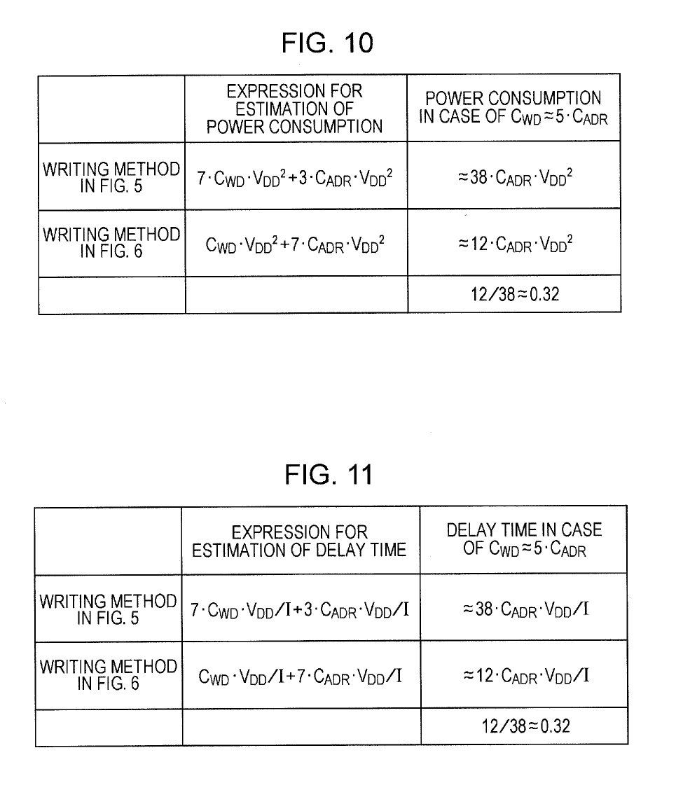

FIG. 10 is a diagram comparing and illustrating estimation of power consumption with applying a comparison result illustrated in FIG. 8 to the CMOS circuit in FIG. 9, and FIG. 11 is a diagram comparing and illustrating estimation of a delay time with applying the comparison result illustrated in FIG. 8 to the CMOS circuit in FIG. 9.

In addition, in FIG. 10 and FIG. 11, a reference symbol C_{WD} indicates a load capacitance (global bit line capacitance) at the time of switching between the high-current driver and the low-current driver, and a reference symbol C_{ADR} indicates a load capacitance (local bit line capacitance) at the time of switching an address.

Here, it is assumed that the C_{WD} is about five times as large as the C_{ADR} (C_{WD}≈5·C_{ADR}). In addition, while the value of the C_{WD} is different depending on each magnetic memory device, this “C_{WD}5·C_{ADR}” is proper, and a greater difference (for example, C_{WD}≈10·C_{ADR}) may also be considered depending on a magnetic memory device.

As illustrated in the upper halves of FIG. 10 and FIG. 8, when the above-mentioned data writing method illustrated in FIG. 5 is applied, an expression for the estimation of the power consumption becomes 7·C_{WD}·VDD²+3·C_{ADR}·VDD², and becomes 38≈C_{ADR}·VDD² if it is assumed that C_{WD}≈5·C_{ADR} is satisfied.

On the other hand, as illustrated in the lower halves of FIG. 10 and FIG. 8, when the above-mentioned data writing method of the first embodiment illustrated in FIG. 6 is applied, an expression for the estimation of the power consumption becomes C_{WD}·VDD²+7·C_{ADR}·VDD², and becomes ≈12·C_{ADR}·VDD² if it is assumed that C_{WD}≈5·C_{ADR} is satisfied.

Accordingly, it is understood that, by applying the data writing method of the first embodiment illustrated in FIG. 6, it may be possible to cause the power consumption at the time of applying the data writing method illustrated in FIG. 5 to be 12/38≈0.32 times, namely, to reduce the power consumption by about 68%.

In addition, as illustrated in the upper halves of FIG. 11 and FIG. 8, when the above-mentioned data writing method illustrated in FIG. 5 is applied, an expression for the estimation of a delay time becomes 7·C_{WD}·VDD/I+3·C_{ADR}·VDD/I, and becomes ≈38·C_{ADR}·VDD/I if it is assumed that C_{WD}≈5·C_{ADR} is satisfied.

On the other hand, as illustrated in the lower halves of FIG. 11 and FIG. 8, when the above-mentioned data writing method of the first embodiment illustrated in FIG. 6 is applied, an expression for the estimation of the delay time becomes C_{WD}·VDD/I+7·C_{ADR}·VDD/I. Furthermore, it is assumed that C_{WD}≈5·C_{ADR} is satisfied, the expression for the estimation of the delay time becomes ≈12·C_{ADR}·VDD/I.

Accordingly, it is understood that, by applying the data writing method of the first embodiment illustrated in FIG. 6, it may be possible to cause the delay time to be 12/38≈0.32 times as much as the delay time at the time of applying the data writing method illustrated in FIG. 5, namely, to reduce the delay time to about 32%.

In this way, by applying the data writing method for the magnetic memory device of the present first embodiment, it may become possible to reduce, to about 32% (less than or equal to one third thereof), the power consumption and the delay time at the time of applying the data writing method for the magnetic memory device described with reference to FIG. 5. In addition, for example, when C_{WD}≈10·C_{ADR} is satisfied, it may become possible to reduce the power consumption and the delay time to about 23% (less than or equal to one fourth thereof).

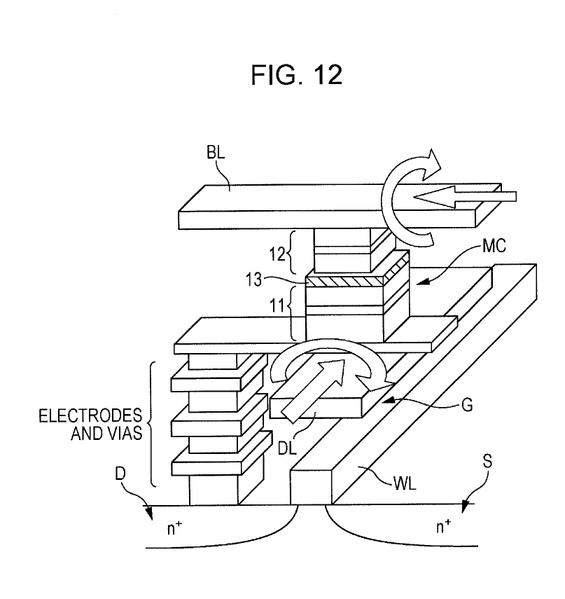

FIG. 12 is a diagram schematically illustrating another example of the magnetic memory device to which the data writing method of the first embodiment is applied, and a diagram illustrating an example where the memory cell (MRAM cell MC) is not a spin injection type but a magnetic field rewritable type magnetic memory device (MRAM).

In FIG. 1 to FIG. 4 described above, by causing the writing current Ic to flow from the bit line BL to the source line SL through the transistor TR with respect to the first MTJ element 11 and the second MTJ element 12 connected in series, the direction of the magnetization (spin) of each of the free layers 113 and 123 is controlled.

On the other hand, in the magnetic memory device (MRAM cell MC) illustrated in FIG. 12, using magnetic fields occurring owing to currents caused to flow through a digit line DL and the bit line BL, writing is performed on the first MTJ element 11 and the second MTJ element 12.

In other words, by causing large currents to flow through the digit line DL and the bit line BL, writing is performed on the first MTJ element 11 serving as a lower bit (LSB), and after that, by causing small currents to flow through the digit line DL and the bit line BL, writing is performed on the second MTJ element 12 serving as an upper bit (MSB).

In addition, while, in FIG. 12, a plurality of electrodes and a plurality of vias are formed between the first MTJ element 11 and the drain D of the transistor TR, this is just an example, and it is to be noted that various modifications may be adopted.

In this way, the data writing method of the present first embodiment may be applied to not only the spin injection type MRAM but also the magnetic field rewritable type MRAM that stores therein data by applying a magnetic field to each of the MTJ elements 11 and 12 in each memory cell and controlling a magnetization direction.

While, in the above-mentioned embodiment, a case has been described where the data writing method is applied to the magnetic memory device including a plurality of four-valued MRAM cells in each of which two MTJ elements are series-connected, a case will described next where a data writing method is applied to a magnetic memory device including a plurality of eight-valued MRAM cells in each of which three MTJ elements are series-connected.

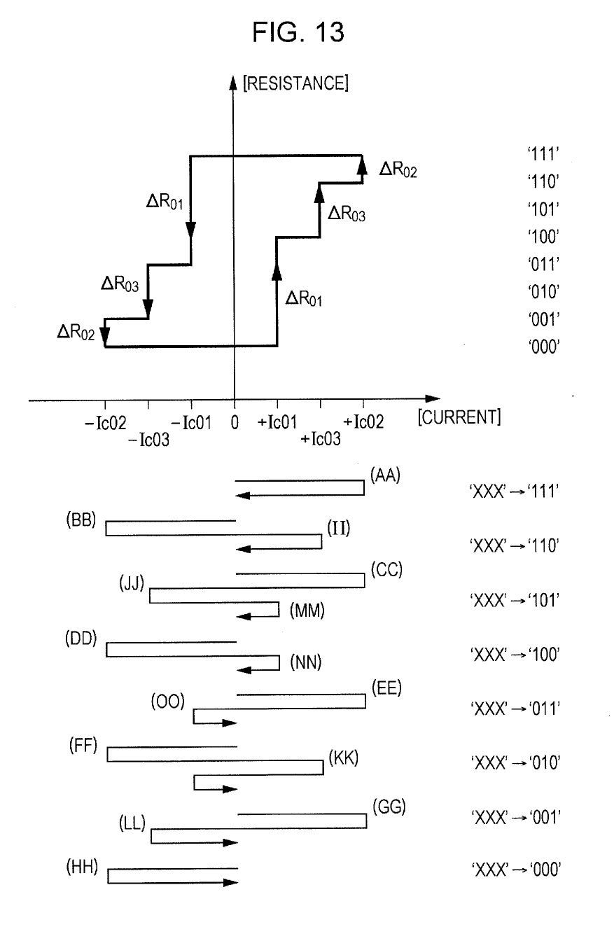

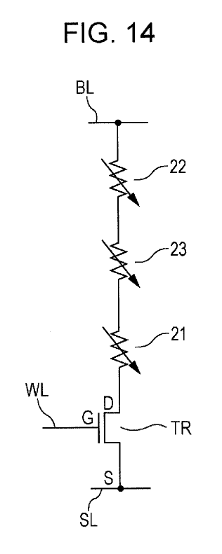

FIG. 13 is a diagram for explaining a data writing method for a magnetic memory device of a second embodiment, and FIG. 14 is a diagram illustrating the equivalent circuit of a magnetic memory device to which the data writing method of the second embodiment is applied.

FIG. 13 corresponds to FIG. 6 (FIG. 4) described above, and FIG. 14 corresponds to FIG. 2 described above. In this regard, however, in FIG. 13 and FIG. 14, an MRAM cell is an eight-valued spin injection type MRAM where three MTJ elements 21, 22, and 23 are series-connected.

Here, the first MTJ element 21 stores therein data of a lower bit (LSB) where the absolute value of a writing current Ic is large (a resistance value is small), and the second MTJ element 22 stores therein data of an upper bit (MSB) where the absolute value of a writing current Ic is small (a resistance value is large).

In addition, in the third MTJ element 23, the absolute value of the writing current Ic and the resistance value thereof have values between those of the first MTJ element 21 and those of the second MTJ element 22, and the third MD element 23 stores therein data of an intermediate bit (Intermediate Significant Bit: ISB).

In addition, as illustrated in FIG. 13, the MRAM cell where the three MTJ elements 21 to 23 are series-connected stores therein data of three bits (eight values: one byte) owing to resistance values according to the combinations of changes ΔR₀₁, ΔR₀₂, and ΔR₀₃ of the resistance values due to the individual MTJ elements.

In the data writing method for the magnetic memory device of the present second embodiment, when data is written into an eight-valued MRAM cell in the state of an arbitrary state “XXX”, writing processing of currents, ±Ic02, whose absolute values are large is performed first on a plurality of addresses using a high-current drive circuit.

Next, writing processing of currents, ±Ic03, whose absolute values are medium is performed using a medium-current drive circuit, and after that, writing processing of currents, ±Ic01, whose absolute values are small is performed using a low-current drive circuit.

Specifically, as illustrated in FIG. 13, when data, “111”, is written into the eight-valued MRAM cell in the state of the arbitrary state “XXX”, the current, +Ic02, is applied (AA). In addition, when data, “110”, is written into the MRAM cell in the state of the arbitrary state “XXX”, the current, −Ic02, is applied (BB), and after that, the current, +Ic02, is applied (II).

Furthermore, when data, “101”, is written into the MRAM cell in the state of the “XXX”, the current, +Ic02, is applied (CC), the current, −Ic03, is applied next (JJ), and after that, the current, +Ic01, is applied (MM).

In addition, when data, “100”, is written into the MRAM cell in the state of the “XXX”, the current, −Ic02, is applied (DD), and after that, the current, +Ic01, is applied (NN). Furthermore, when data, “011”, is written into the MRAM cell in the state of the arbitrary state “XXX”, the current, +Ic02, is applied (EE), and after that, the current, −Ic01, is applied (OO).

In addition, when data, “010”, is written into the MRAM cell in the state of the “XXX”, the current, −Ic02, is applied (FF), furthermore the current, +Ic03, is applied (KK), and after that, the current, −Ic01, is applied (PP).

Furthermore, when data, “001”, is written into the MRAM cell in the state of the “XXX”, the current, +Ic02, is applied (GG), and after that, the current, −Ic03, is applied (LL). In addition, when data, “000”, is written into the MRAM cell in the state of the “XXX”, the current, −Ic02, is applied (HH).

Here, for example, when eight different pieces of data, “111”, “110”, “101”, “100”, “011”, “010”, “001”, and “000”, are written into eight eight-valued MRAM cells corresponding to eight addresses, processing is performed in the order of (AA) to (PP).

According to the data writing method for the magnetic memory device of the present second embodiment, writing processing operations (AA) to (HH) of the currents, ±Ic02, whose absolute values are the largest are performed first using the high-current drive circuit (high-current driver).

Next, writing processing operations (II) to (LL) of the current, ±Ic03, whose absolute values are medium are performed using the medium-current drive circuit (medium-current driver). Furthermore, after that, writing processing operations (MM) to (PP) of the current, ±Ic01, whose absolute values are the smallest are performed using the low-current driver (low-current driver).

In other words, first writing processing operations due to +Ic02 and −Ic02 where the absolute values of the writing currents thereof are the largest are performed, and next writing processing operations due to +Ic03 and −Ic03 where the absolute values of the writing currents thereof are medium are performed. After that, writing processing operations due to +Ic01 and −Ic01 where the absolute values of the writing currents thereof are the smallest are performed.

Accordingly, switching between the high-current driver used for the writing of the currents, ±Ic02, whose absolute values are the largest and the medium-current driver used for the writing of the currents, ±Ic03, whose absolute values are medium is performed only once in such a way as (HH)→(II).

Furthermore, switching between the medium-current driver used for the writing of the currents, ±Ic03, whose absolute values are medium and the low-current driver used for the writing of the currents, ±Ic01, whose absolute values are the smallest is performed only once in such a way as (LL)→(MM).

According to the data writing method for the magnetic memory device of the present second embodiment, by reducing the number of times switching of a writing current drive circuit whose load capacitance is large is performed, power consumption at the time of writing is reduced, and a time taken for charge and discharge is shortened. Therefore, it may be possible to speed up a writing operation.

In addition, the present embodiment is not limited to a magnetic memory device storing therein four-valued or eight-valued data, and may also be applied to a magnetic memory device including a plurality of memory cells, each of which stores therein 2ⁿ-valued data by series-connecting MTJ elements whose writing current values and resistance values are different and whose number is n (n is a natural number greater than or equal to 2).

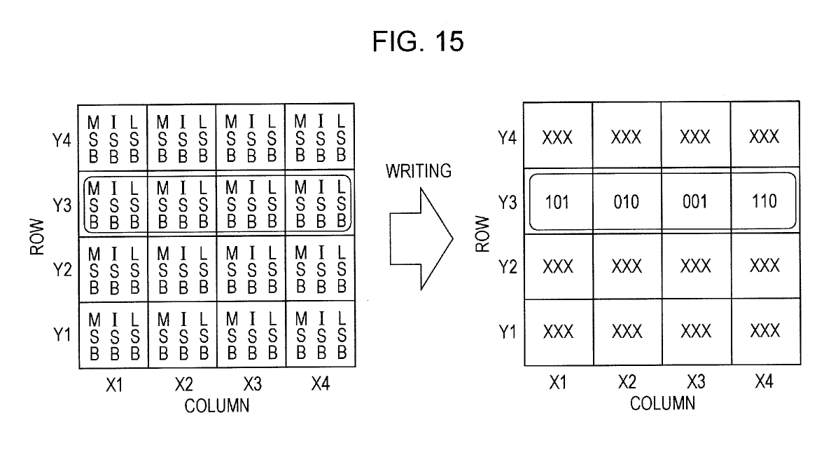

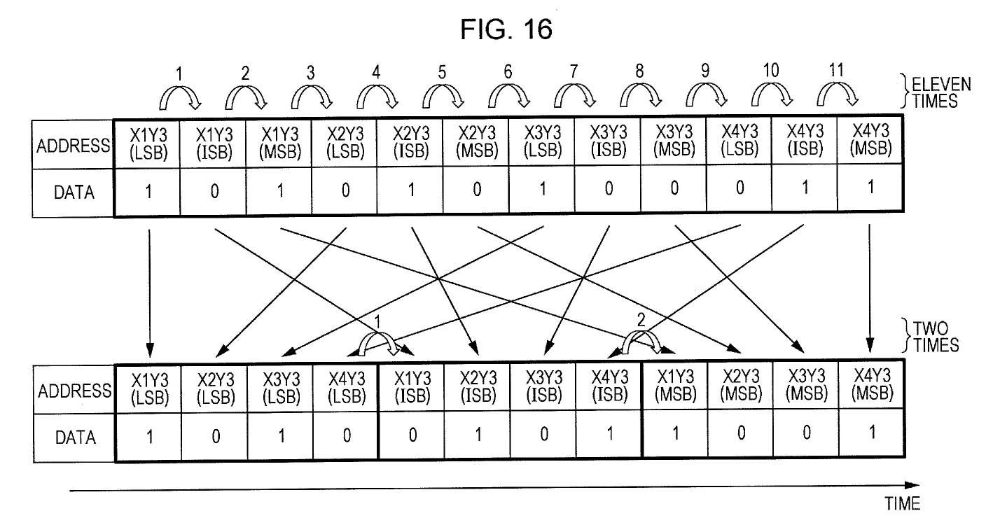

FIG. 15 is a diagram illustrating another example of data written into a magnetic memory device, and a diagram illustrating an example of the application of the above-mentioned second embodiment. FIG. 16 is a diagram illustrating writing processing due to the data writing method of the second embodiment with comparing the writing processing with writing processing equivalent to the writing method in FIG. 5.

FIG. 15 corresponds to FIG. 7 described above, and FIG. 16 corresponds to FIG. 8 described above. In this regard, however, in FIG. 15 and FIG. 16, the MRAM cell is caused to store therein eight-valued data.

In other words, FIG. 15 illustrates a case where, in a 4×4 memory cell array, data including four bytes, “101”, “010”, “001”, and “110”, is written into addresses, “X1Y3”, “X2Y3”, “X3Y3”, and “X4Y3”.

The upper half of FIG. 16 illustrates processing performed when the data writing method for the magnetic memory device, described with reference to FIG. 5, is applied and the lower half of FIG. 16 illustrates processing performed when the data writing method for the magnetic memory device of the present second embodiment, described with reference to FIG. 13, is applied.

First, as illustrated in the upper half of FIG. 16, when a case is assumed where the data writing method in FIG. 5 is applied to an eight-valued MRAM cell, drive circuits having different currents are switched 11 times so as to write four-byte date into four addresses illustrated in FIG. 15.

In other words, with respect to each of the four addresses, the writing processing for the LSB (the first MTJ element 21), the writing processing for the ISB (the third MTJ element 23), and the writing processing for the MSB (the second MTJ element 22) are performed,

Therefore, switching between the writing currents, ±Ic02 and ±Ic03, and switching between the writing currents, ±Ic03 and ±Ic01, are performed 11 times in total.

On the other hand, as illustrated in the lower half of FIG. 16, when four-byte data is written into four addresses illustrated in FIG. 15 with the data writing method of the second embodiment in FIG. 13 being applied, the number of times the drive circuits having different currents are switched may be two.

In other words, with respect to the four addresses, the writing processing for all the ISBs (the third MTJ elements 23) is performed after the writing processing for all the LSBs (the first MTJ elements 21) has been performed, and after that, the writing processing for all the MSBs (the second MTJ elements 22) is performed.

Therefore, the number of times drive circuits are switched becomes only two, namely, switching performed between the writing currents, ±Ic02 and ±Ic03, and switching performed between the writing currents, ±Ic03 and ±Ic01.

Specifically, as is clear from arrows in FIG. 16, when the data writing method of the present second embodiment is applied, the writing processing of the writing currents, ±Ic02, is performed on the LSB of the address of “X1Y3”, the LSB of the address of “X2Y3”, the LSB of the address of “X3Y3”, and the LSB of the address of “X4Y3”.

After that, the writing processing of the writing currents, ±Ic03, is performed on the ISB of the address of “X1Y3”, the ISB of the address of “X2Y3”, the ISB of the address of “X3Y3”, and the ISB of the address of “X4Y3”. Furthermore, after that, the writing processing of the writing currents, ±Ic01, is performed on the MSB of the address of “X1Y3”, the MSB of the address of “X2Y3”, the MSB of the address of “X3Y3”, and the MSB of the address of “X4Y3”.

Accordingly, switching between the high-current driver used for the writing of the currents, ±Ic02, whose absolute values are the largest and the medium-current driver used for the writing of the currents, ±Ic03, whose absolute values are medium is performed between the LSB of “X4Y3” and the ISB of “X1Y3” only once.

In addition, switching between the medium-current driver used for the writing of the currents, ±Ic03, whose absolute values are medium and the low-current driver used for the writing of the currents, ±Ic01, whose absolute values are the smallest is performed between the ISB of “X4Y3” and the MSB of “X1Y3” only once.

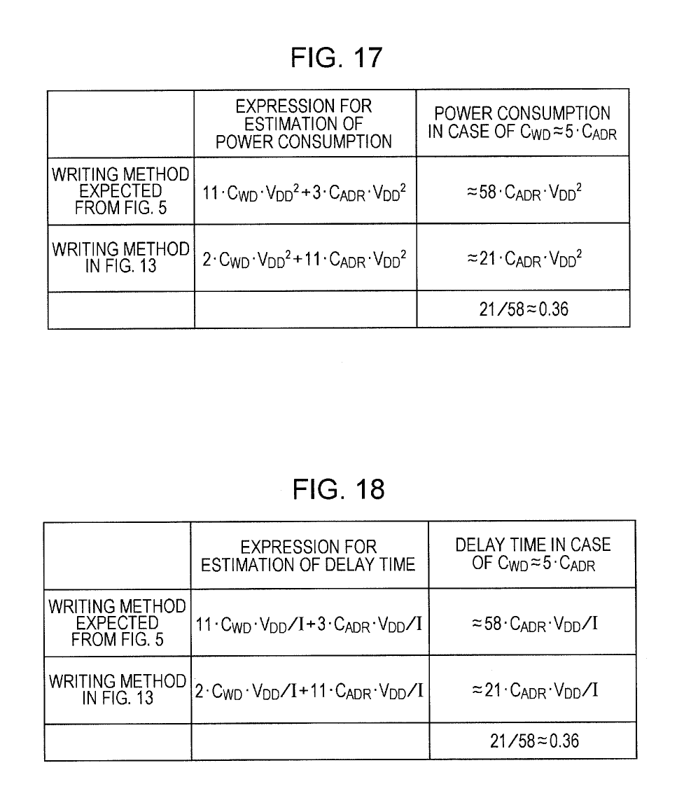

FIG. 17 is a diagram comparing and illustrating estimation of power consumption with applying a comparison result illustrated in FIG. 16 to the CMOS circuit in FIG. 9, and FIG. 18 is a diagram comparing and illustrating estimation of a delay time with applying the comparison result illustrated in FIG. 16 to the CMOS circuit in FIG. 9. Here, FIG. 17 corresponds to FIG. 10 described above, and FIG. 18 corresponds to FIG. 11 described above.

In addition, in FIG. 17 and FIG. 18, a reference symbol C_{WD} indicates a load capacitance (global bit line capacitance) at the time of switching between the high-current driver and the medium-current driver or at the time of switching between the medium-current driver and the low-current driver. In addition, a reference symbol C_{ADR} indicates a load capacitance (local bit line capacitance) at the time of switching an address. Here, it is assumed that the C_{WD} is about five times as large as the C_{ADR} (C_{WD}5·C_{ADR}).

As illustrated in the upper halves of FIG. 17 and FIG. 16, when a data writing method expected from FIG. 5 is applied, an expression for the estimation of the power consumption becomes 11·C_{WD}·VDD²3·C_{ADR}·VDD², and becomes ≈58·C_{ADR}·VDD² if it is assumed that C_{WD}5·C_{ADR} is satisfied.

On the other hand, as illustrated in the lower halves of FIG. 17 and FIG. 16, when the above-mentioned data writing method of the second embodiment illustrated in FIG. 13 is applied, an expression for the estimation of the power consumption becomes 2·C_{WD}·VDD²+11·C_{ADR}·VDD². In addition, if it is assumed that C_{WD}5·C_{ADR} is satisfied, the expression for the estimation of the power consumption becomes ≈21·C_{ADR}·VDD².

Accordingly, it is understood that, by applying the data writing method of the second embodiment illustrated in FIG. 13, it may be possible to cause the power consumption at the time of applying the data writing method expected from FIG. 5 to be 21/58≈0.36 times, namely, to reduce the power consumption by about 64%.

In addition, as illustrated in the upper halves of FIG. 18 and FIG. 16, when the data writing method expected from FIG. 5 is applied, an expression for the estimation of a delay time becomes 11·C_{WD}·VDD/I+3·C_{ADR}·VDD/I. In addition, the expression for the estimation of the delay time becomes ≈58·C_{ADR}·VDD/I if it is assumed that C_{WD}≈5·C_{ADR} is satisfied.

On the other hand, as illustrated in the lower halves of FIG. 18 and FIG. 16, when the above-mentioned data writing method of the second embodiment illustrated in FIG. 13 is applied, an expression for the estimation of the delay time becomes 2·C_{WD}·VDD/I+11·C_{ADR}·VDD/I. Furthermore, it is assumed that C_{WD}≈5·C_{ADR} is satisfied, the expression for the estimation of the delay time becomes ≈21·C_{ADR}·VDD/I.

Accordingly, it is understood that, by applying the data writing method of the second embodiment illustrated in FIG. 13, it may be possible to cause the delay time to be 21/58 ≈0.36 times as much as the delay time at the time of applying the data writing method expected from FIG. 5, namely, to reduce the delay time to about 36%.

In this way, by applying the data writing method for the magnetic memory device of the present second embodiment, it may become possible to reduce, to about 36% (nearly one third), the power consumption and the delay time at the time of applying the data writing method for the magnetic memory device expected from FIG. 5.

In this way, according to the data writing method for the magnetic memory device of the present second embodiment, it may be possible to reduce power consumption at the time of writing data and improve an operation speed. In addition, the MRAM cell may not be an eight-valued spin injection type MRAM cell where MTJ elements are series-connected but may also be an eight-valued magnetic field rewritable type MRAM cell. Furthermore, it is to be noted that the data writing method of the present second embodiment may also be applied to a multivalued (for example, 16-valued) MRAM cell where four or more MTJ elements are series-connected.

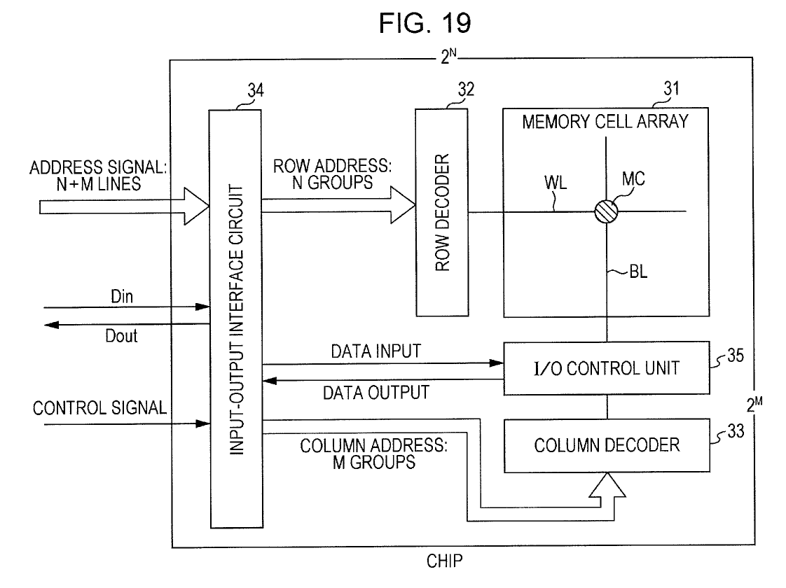

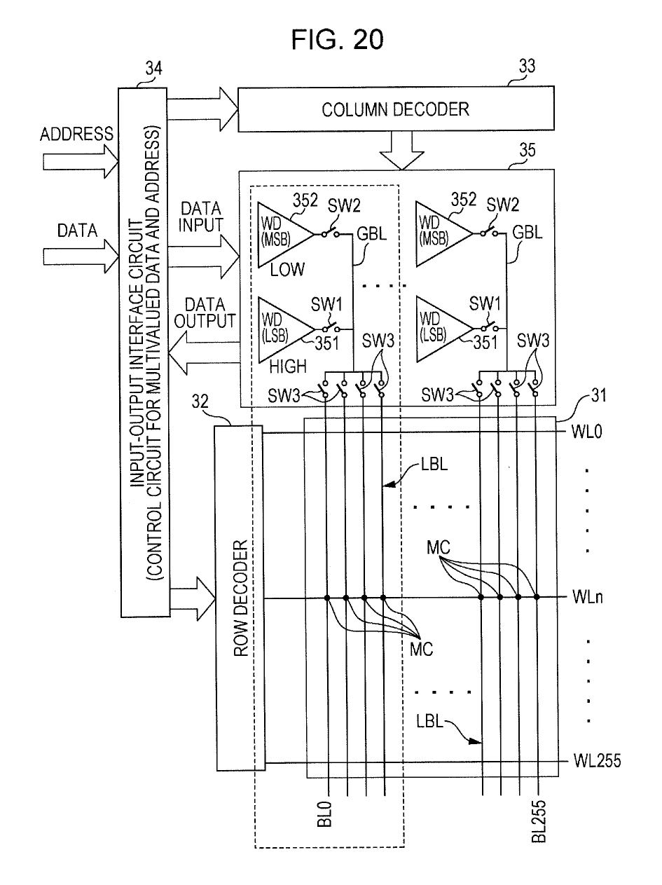

FIG. 19 is a block diagram illustrating an embodiment of a magnetic memory device, and FIG. 20 is a block diagram illustrating in more detail the magnetic memory device illustrated in FIG. 19.

As illustrated in FIG. 19 and FIG. 20, the magnetic memory device of the present embodiment includes a memory cell array 31, a row decoder 32, a column decoder 33, an input-output interface circuit 34, and an I/O control unit 35.

As illustrated in FIG. 20, the I/O control unit 35 includes a plurality of high-current drive circuits (high-current drivers: WD (LSB)) 351 and a plurality of low-current drive circuits (low-current drivers: WD (MSB)).

In addition, the I/O control unit 35 includes a plurality of switches SW1 controlling connection between the individual high-current drivers 351 and individual global bit lines GBL and a plurality of switches SW2 controlling connection between the individual low-current drivers 352 and the individual global bit lines GBL.

Furthermore, the I/O control unit 35 includes a plurality of switches SW3 controlling connection between the individual global bit lines GBL and a plurality of local bit lines LBL. In addition, MRAM cells MC are individually disposed at intersecting points between the individual local bit line LBL and the individual word lines WL.

In other words, the memory cell array 31 includes a plurality of memory cells (MRAM cells MC) disposed in a matrix manner at individual intersecting points between word lines WL0 to WL255 and bit lines (local bit lines) BL0 to BL255.

In addition, the MRAM cell MC may be various memory cells such as, for example, the memory cell described with reference to the above-mentioned FIG. 1, FIG. 2, and FIG. 6 or the memory cell described with reference to FIG. 12, or FIG. 13 and FIG. 14.

The row decoder 32 decodes a row address (for example, N groups) output from the input-output interface circuit 34 and selects a corresponding word line WL. The column decoder 33 decodes a column address (for example, M groups) output from the input-output interface circuit 34 and selects a corresponding bit line BL through the I/O control unit 35.

The input-output interface circuit 34 includes address signal lines that receive addresses from the outside (for example, a CPU (Central processing Unit), DMA (Direct Memory Access), or the like) and whose number is N+M, and receives a control signal from the outside. Furthermore, the input-output interface circuit 34 receives input data Din through a data bus or the like, and outputs output data Dout.

Here, for example, the input-output interface circuit 34 converts data and addresses which are to be input and outputs the converted data and addresses so that the number of times switching is performed between current drivers becomes a minimum with respect to a plurality of addresses (for example, one byte or four bytes).

The I/O control unit 35 receives a data input from the input-output interface circuit 34 and the output of the column decoder 33, and controls the switches SW1 to SW3. In other words, the I/O control unit 35 receives the output of the input-output interface circuit 34 and the output of the column decoder 33, and controls the switches SW1 to SW3 so that the number of times switching is performed between the individual current drivers 351 and 352 becomes a minimum.

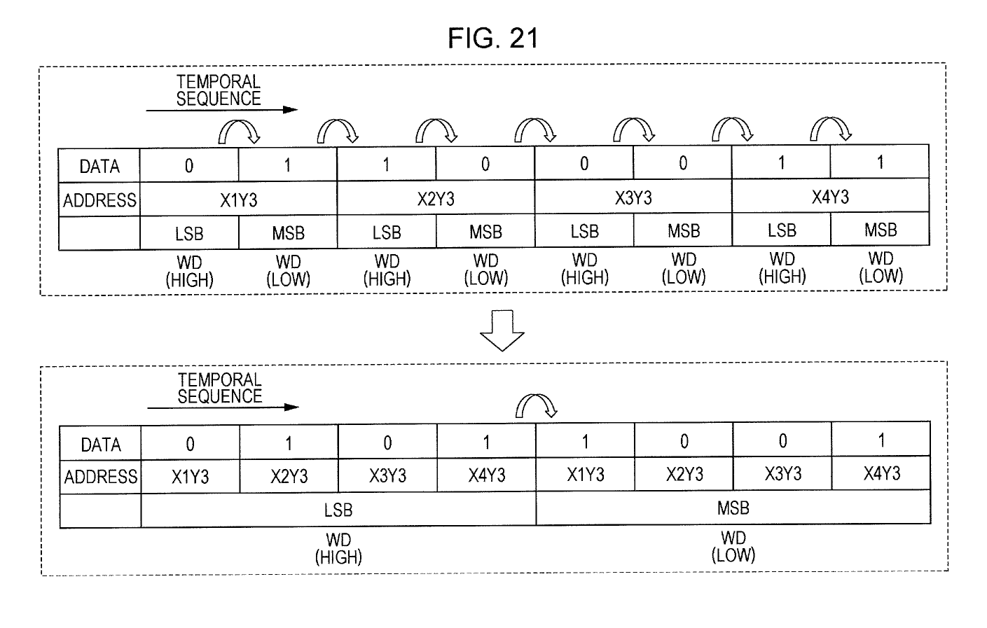

FIG. 21 is a diagram for explaining an example of the operation of the control circuit in FIG. 20, and a diagram simplistically illustrating the above-mentioned FIG. 8.

The upper half of FIG. 21 illustrates, for example, an operation performed when addresses and data are directly input to an MRAM not having the input-output interface circuit 34 and I/O control unit 35 described with reference to FIG. 19 and FIG. 20 and the writing processing illustrated in FIG. 7 is performed thereon.

The lower half of FIG. 21 illustrates, for example, an operation performed when the writing processing illustrated in FIG. 7 is performed on an MRAM having a control circuit (the input-output interface circuit 34 and I/O control unit 35) described with reference to FIG. 19 and FIG. 20.

According to an embodiment of the magnetic memory device illustrated in FIG. 19 and FIG. 20, data and addresses such as in the upper half of FIG. 21, input from the outside, are converted in such a way as in the lower half of FIG. 21 and output, owing to the input-output interface circuit (control circuit for multivalued data and addresses) 34.

In other words, the input-output interface circuit 34 receives, for example, data and addresses such as in the upper half of FIG. 21, and outputs the data and addresses, converted in such a way as in the lower half of FIG. 21.

In addition, the input-output interface circuit 34 having the above-mentioned conversion function may be realized, for example, using a logic circuit or using a look-up table (LUT), an arithmetic unit, and the like.

The addresses converted by the input-output interface circuit 34 are output to the row decoder 32 and the column decoder 33, and the data converted by the input-output interface circuit 34 is output to the I/O control unit 35.

In the I/O control unit 35, the plural high-current drivers 351, the plural low-current drivers 352, and the switches SW1 to SW3 are provided, and writing processing is performed in accordance with data and address such as in the lower half of FIG. 21, converted by the input-output interface circuit 34.

According to the magnetic memory device of the present embodiment, when one-byte is written into four four-valued MRAM cells MC connected to four bit lines BL (local bit lines LBL), switching between the high-current driver 351 and the low-current driver 352 is performed only once.

In other words, in the I/O control unit 35, while the four bit lines BL are switched by the switch SW3 in accordance with the output from the column decoder and each MRAM cell MC is selected, the two current drivers 351 and 352 are switched by the switches SW1 and SW2. Here, switching between the high-current driver 351 and the low-current driver 352 may be simply performed only once.

In addition, while the operation description illustrated in FIG. 21 is described with being typified by one bit within the bit configuration (for example, x8, x16 bits, or the like) of a memory, this processing is performed in parallel on 8 bits or 16 bits.

In addition, the magnetic memory device of the present embodiment is not limited to the magnetic memory device illustrated FIG. 19 and FIG. 20, and various circuits may be available to which each embodiment of the above-mentioned data writing method for the magnetic memory device is able to be applied.

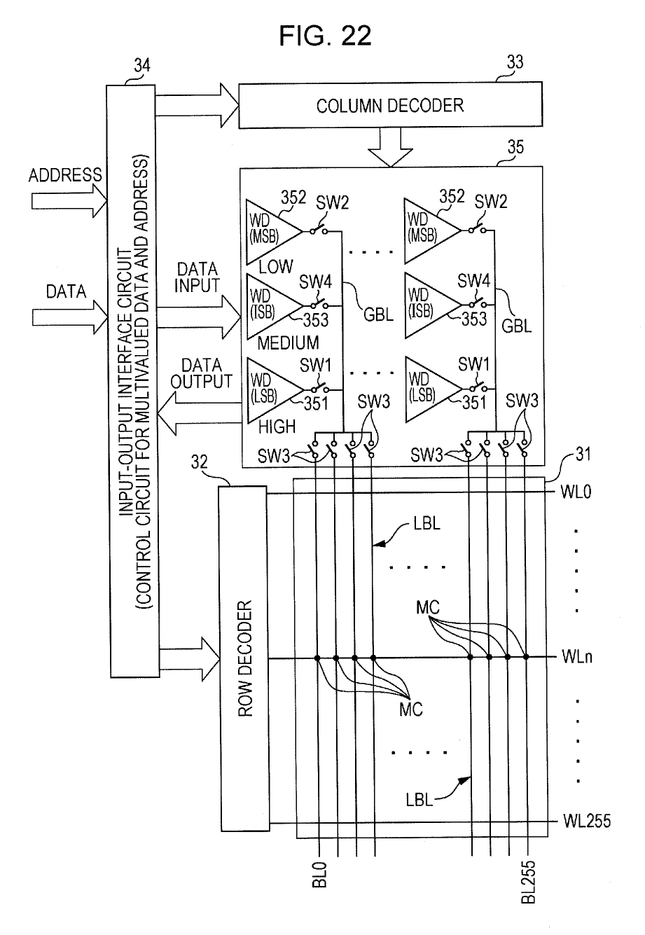

FIG. 22 is a block diagram illustrating an example of a modification to the magnetic memory device illustrated in FIG. 20, and illustrates a magnetic memory device applied to the eight-valued spin injection type MRAM where the three MTJ elements 21, 22, and 23 are series-connected in the memory cell MC described with reference to FIG. 13 to FIG. 18.

In each memory cell MC, owing to the high-current driver 351, writing processing is performed on the first MTJ element 21 where the absolute value of the writing current thereof is large, and owing to the low-current driver 352, writing processing is performed on the second MTJ element 22 where the absolute value of the writing current thereof is small.

In addition, in each memory cell MC, owing to the medium-current driver 353, writing processing is performed on the third MTJ element 23 that has a writing current midway between the writing current of the first MTJ element 21 and the writing current of the second MTJ element 22.

As illustrated in FIG. 22, in the present example of a modification, the I/O control unit 35 includes a plurality of medium-current drive circuits (medium-current drivers: WD (ISB)) and a plurality of switches SW4, in addition to the plural high-current drivers 351, the plural low-current drive drivers 352, and the plural switches SW1 to SW3.

Here, the input-output interface circuit 34 receives, for example, data and addresses such as in the upper half of FIG. 16, and outputs the data and addresses, converted in such a way as in the lower half of FIG. 16.

In addition, the I/O control unit 35 receives a data input from the input-output interface circuit 34 and the output of the column decoder 33, and controls the switches SW1 to SW4. In other words, the I/O control unit 35 receives the output of the input-output interface circuit 34 and the output of the column decoder 33, and controls the switches SW1 to SW4 so that the number of times switching is performed between the individual current drivers 351 to 353 becomes a minimum.

Accordingly, as described with reference to FIG. 13 to FIG. 18, it may be possible to reduce, from 11 to 2, the number of times the drive circuits (current drivers 351 to 353) having different currents are switched, and it may be possible to improve the operation speed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A magnetic memory device including a plurality of memory cells, each of which stores therein 2ⁿ-valued data by series-connecting MTJ elements whose writing current values and resistance values are different and whose number is n (n is a natural number greater than or equal to 2), the magnetic memory device comprising:
a first current driver configured to perform writing on a first MTJ element of a first writing current value in the n MTJ elements;
a second current driver configured to perform writing on a second MTJ element of a second writing current value lower than the first writing current value in the n MTJ elements; and
a control circuit configured to control so that, in the plural memory cells corresponding to a plurality of addresses, after data writing has been performed on the first MTJ element owing to the first current driver, data writing is performed on the second MTJ element owing to the second current driver.

2. The magnetic memory device according to claim 1, wherein
each of the memory cells is configured to store therein four-valued data owing to two MTJ elements including the first MTJ element and the second MTJ element, and
the control circuit controls so that, in the plural memory cells corresponding to the plural addresses, after data writing has been performed on all the first MD elements owing to the first current driver, data writing is performed on all the second MTJ elements owing to the second current driver.

3. The magnetic memory device according to claim 1, wherein
each of the memory cells is configured to store therein eight-valued data owing to the first MTJ element, the second MD element, and a third MTJ element of a third writing current value lying between the first writing current value and the second writing current value,
the magnetic memory device further includes a third current driver configured to perform writing on the third MTJ element, and
the control circuit controls so that, in the plural memory cells corresponding to the plural addresses, after data writing has been performed on all the first MTJ elements owing to the first current driver, data writing is performed on all the third MTJ elements owing to the third current driver and furthermore after that, data writing is performed on all the second MTJ elements owing to the second current driver.

4. The magnetic memory device according to claim 1, wherein
the control circuit includes
an input-output interface circuit configured to convert and output data and addresses, which are to be input, so that the number of times switching is performed between the individual current drivers becomes a minimum with respect to the plural addresses.

5. The magnetic memory device according to claim 1, wherein
each of the MTJ elements in each of the memory cells includes a first magnetic material layer whose magnetization direction is fixed, a second magnetic material layer whose magnetization direction is variable, and an insulation layer provided between the first magnetic material layer and the second magnetic material layer.

6. The magnetic memory device according to claim 5, wherein
the individual MTJ elements in each of the memory cells have a same structure and different areas.

7. The magnetic memory device according to claim 5, wherein
the magnetic memory device is a spin injection type MRAM that injects a current into each of the MTJ elements in each of the memory cells and stores therein data by controlling a magnetization direction.

8. The magnetic memory device according to claim 5, wherein
the magnetic memory device is a magnetic field rewritable type MRAM that applies a magnetic field to each of the MTJ elements in each of the memory cells and stores therein data by controlling a magnetization direction.

9. A data writing method for a magnetic memory device that includes a plurality of memory cells, each of which stores therein 2ⁿ-valued data by series-connecting MTJ elements whose writing current values and resistance values are different and whose number is n (n is a natural number greater than or equal to 2), the data writing method comprising:
after, in the plural memory cells corresponding to a plurality of addresses, data writing has been performed on a first MTJ element of a first writing current value in the n MTJ elements,
performing writing on a second MTJ element of a second writing current value lower than the first writing current value.

10. The data writing method for a magnetic memory device according to claim 9, wherein
each of the memory cells is configured to store therein four-valued data owing to two MTJ elements including the first MTJ element and the second MTJ element, and
in the plural memory cells corresponding to the plural addresses, after data writing has been performed on all the first MTJ elements, data writing is performed on all the second MTJ elements.

11. The data writing method for a magnetic memory device according to claim 9, wherein
each of the memory cells is configured to store therein eight-valued data owing to the first MTJ element, the second MTJ element, and a third MTJ element of a third writing current value lying between the first writing current value and the second writing current value, and
in the plural memory cells corresponding to the plural addresses, after data writing has been performed on all the first MTJ elements, data writing is performed on all the third MTJ elements and furthermore after that, data writing is performed on all the second MTJ elements.

12. The data writing method for a magnetic memory device according to claim 9, wherein
each of the MTJ elements in each of the memory cells includes a first magnetic material layer whose magnetization direction is fixed, a second magnetic material layer whose magnetization direction is variable, and an insulation layer provided between the first magnetic material layer and the second magnetic material layer.

13. The data writing method for a magnetic memory device according to claim 12, wherein
the individual MTJ elements in each of the memory cells have a same structure and different areas.

14. The data writing method for a magnetic memory device according to claim 12, wherein
the magnetic memory device is a spin injection type MRAM that injects a current into each of the MTJ elements in each of the memory cells and stores therein data by controlling a magnetization direction.

15. The data writing method for a magnetic memory device according to claim 12, wherein
the magnetic memory device is a magnetic field rewritable type MRAM that applies a magnetic field to each of the MTJ elements in each of the memory cells and stores therein data by controlling a magnetization direction.
